(19) United States
(12) Patent Application Publication
(10) Pub. No.: US 2009/0154127 A1
(43) Pub. Date: Jun. 18, 2009

(54) PCB Embedded Electronic Elements Structure And Method Thereof

(76) Inventors: Ting-Hao Lin, Taipei (TW); Chien-Wei Chang, Taoyuan (TW)

Correspondence Address: LIN & ASSOCIATES INTELLECTUAL PROPERTY, INC., P.O. BOX 2339, SARATOGA, CA, 95070-0339, US

(21) Appl. No.: 11/958,384

(22) Filed: Dec. 18, 2007

(51) Int. Cl. H05K 1/16; H05K 3/00; H05K 1/00

(52) U.S. Cl. 361/782; 29/829; 361/760

(57) ABSTRACT

Structure of embedded electronic elements in a PCB (printed circuit board) and the method for embedding the structure include assembling the electronic elements (such as a capacitor, a resistor, a diode) on the PCB, and then laminating other circuit layers. A group of electrodes of the electronic elements are aligned to a group of junctions on the PCB, respectively; the electronic elements are assembled on the group of junctions on the PCB; and then a metal layer is laminated on the PCB using gel film (dielectric gel) in which the PCB includes already embedded electronic elements.

### BACKGROUND OF THE INVENTION

1. Field of the Invention

The present invention relates generally to a structure of embedded electronic elements or components in the PCB and the method for embedding thereof, and in particular, to a structure of embedded electronic elements and components in the PCB, and the method for embedding for achieving a lower inductance.

2. The Prior Arts

The so-called embedded passives, through the use of the thin core manufacture of the multilayer PCB for carrying out the etching or the printing processes, and then the capacitors or the resistors are manufactured on the thin core directly, when after being laminated for becoming the multilayer PCB, thereby can be used to replace the discrete passive elements which are welded onto the board during assembling fabrication, so as to save on board area for use by the active devices and the corresponding circuits.

The embedded/implanted/buried technology which is started by the Ohmega-ply Company using the matte side of the original copper-cladding on the innerlayer surface, and to attach the nickel phosphorus alloy layer at the upper thin film layer, which is regarded as the resistive element, to be laminated to become the thin core. Then, the photoresist technology is used twice, as well as the etching technology is performed three times to form the required film “resistor” on a specific designated location. Because the above resistor is embedded inside the thin core; therefore, it is commonly known also as a Buried Resistor (BR).

Thereafter, in 1992, a PCB manufacturer in the U.S.A. named Zycon, has used the upper layers inside a multilayer PCB, outside of the original Vcc/GND thin core, to add in an extremely thin (2-4 mil) dielectric layer as the thin core, and using the vast area of the parallel copper sheet/foil of the thin core for manufacturing the integrated capacitor, having the trade name of Buried Capacitor™ (BC). It has advantages such as reducing interference, providing charge capacity, and steady voltage while operating under fundamental frequencies. Zycon Company once applied for several patents relating to the BC (namely, U.S. Pat. Nos. 5,079,069, 5,161,086, and 5,155,655).

The conventional low inductance-capacitance typically shortens the electrical path for reducing capacitance. That is because the smaller the scanning range of the electrical path, the smaller the capacitance is accordingly. Thus, both the gap between the paths and the thickness (height) of the connections should be reduced.

In the case of assembling the embedded capacitors, if the distributed element assembling method is adopted, the typical procedure includes is to manufacture the PCB first, later followed by assembling, and then to manufacture the PCB.

Referring to FIG. 1, FIG. 1 is a schematic view showing a conventional method of assembling a capacitor. As shown in FIG. 1, according to this conventional method, the PCB includes an insulating layer 12 at least, and a set of junctions 14 inside of the insulating layer 12, an outer circuit layer 16 on the outside of the insulating layer 12, and a blind hole 15 for conducting between the set of junctions 14 and the outer circuit layer 16. The capacitor 10 includes a group of electrodes 10a at least, and there is an electrical connection between the group of electrodes 10a and the set of junctions 14.

Under the aforementioned method, the range which a circuit path 18 covers includes the thickness of the insulating layer 12 and the span covered by the electronic elements. Although such method has shown improvements over other conventional surface-mounted methods for manufacturing electronic components and elements in terms of electrical performance; however, there is still room for improvement.

While assembling the embedded capacitor, some manufacturers use the method of punching directly for installing the capacitors in the specific designated locations within the PCB, and then carrying on the laser drilling process for fabricating the circuit path.

Referring to FIG. 2, FIG. 2 is a schematic view showing another conventional method of assembling the capacitor. As shown in FIG. 2, according to this method, the capacitor structure includes an insulating layer 12 at least, an outer circuit layer 16 on the outside of the insulating layer 12, a group of electrodes 10a for electrically connecting a capacitor 10, and a blind hole 15 (used as the junction) on the outer circuit layer 16.

Compared with FIG. 1, the capacitor structure shown in FIG. 2 has a lower inductance value because the circuit path 18 does not pass through the insulating layer 12 to shorten the distance; however, there is difficulty in controlling the contraposition by using this method, and also the manufacturing of many paths or channels in one capacitor is also more difficult. As for the selection and use of the electronic components, because the blind hole 15 which is connected should be manufactured directly, the selection on the metal processing is relatively limited.

In a word, the above methods can achieve similar amounts of capacitance, but the performance behavior in inductance will be different, and distinguishable disadvantages pertaining to the fabrication processes are also evident in the above methods.

### SUMMARY OF THE INVENTION

A primary objective of the present invention is to provide a structure and method for embedding electronic elements in the PCB using a group of electrodes on an electronic element (e.g. a capacitor, a resistor, and a diode) for electrically connecting with a set of junctions on the PCB directly, without passing through the insulating layer for achieving shorter circuit path and lower inductance.

Based on the above purposes, the structure and method for embedding electronic elements in the PCB according to the present invention mainly includes a group of electrodes in the electronic element to align to a group of junctions on the PCB, respectively; and the electronic element are assembled on the PCB through the group of junctions; and then the metal layer is laminated on the PCB, which already has the embedded electronic element, using the gel film. Thus, not only the degree of difficulty of the process is lower (without having to consider contraposition, and without manufacturing many paths and blind holes), but also the inductance value is lower (because of direct electrical connection without passing through the insulating layer for achieving a shorter circuit path).

### BRIEF DESCRIPTION OF THE DRAWINGS

The present invention will be apparent to those skilled in the art by reading the following detailed description of a preferred embodiment thereof, with reference to the attached drawings, in which:

FIG. 1 is a schematic diagram showing a conventional method of assembling a capacitor;

FIG. 2 is a schematic diagram showing another conventional method of assembling a capacitance; and

FIGS. 3A-3E are a plurality of schematic diagrams showing a method for embedding a plurality of electronic elements in the PCB according to an embodiment of the present invention.

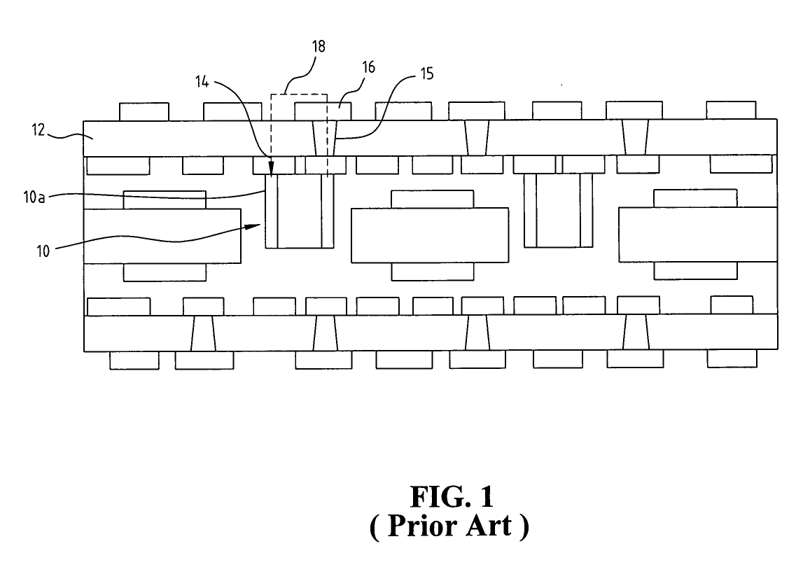

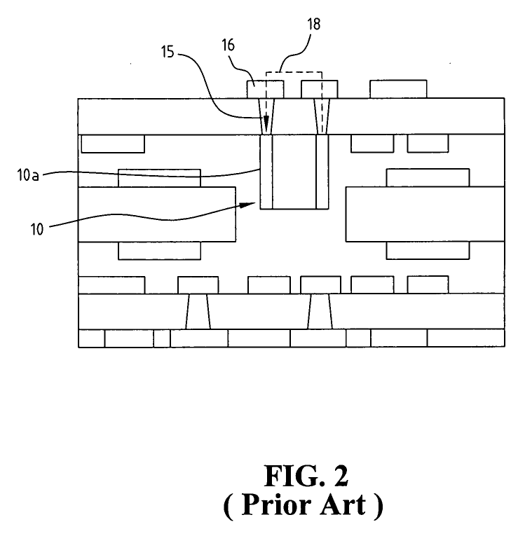

### DETAILED DESCRIPTION OF THE EMBODIMENTS

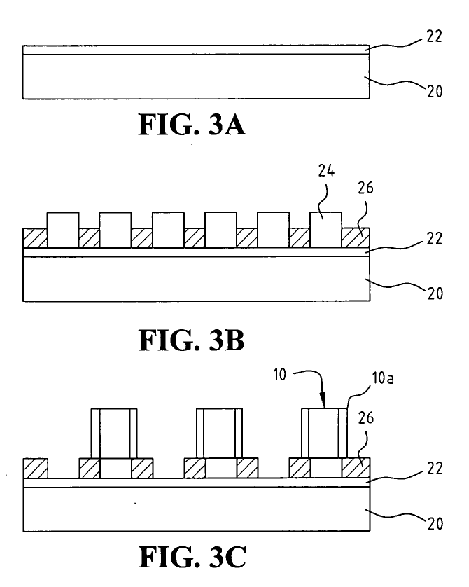

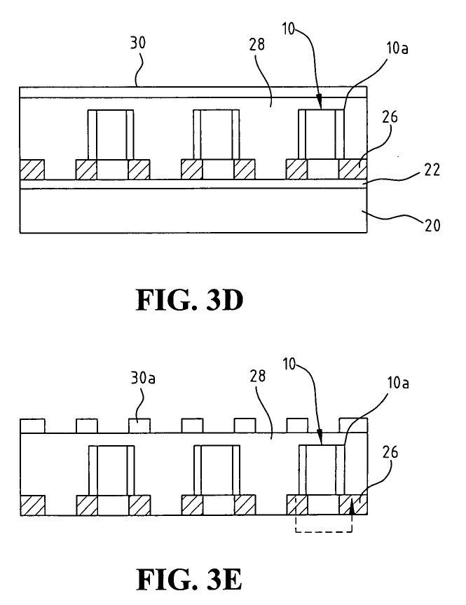

Referring to FIGS. 3A-3E, FIGS. 3A-3E are a plurality of schematic diagrams showing a method for embedding a plurality of electronic elements in the PCB in accordance with an embodiment of the present invention. Among the aforementioned schematic diagrams, FIGS. 3A-3B and FIG. 3E illustrate a plurality of optional processes according to the embodiment of the present invention; and FIGS. 3C-3D illustrate a plurality of main manufacturing procedures in accordance to the embodiment of the present invention. Therefore, the following first describes the procedures shown in FIGS. 3C-3D, followed by the description of the manufacturing procedures illustrated in FIGS. 3A-3B and 3E.

Briefly, the method in accordance with the embodiment of the present invention for embedding a plurality of electronic elements 10 in the PCB mainly includes: assembling the electronic elements 10 (e.g. a capacitor, a resistor, and a diode) on the PCB as shown in FIG. 3C, and laminating to form other circuit layers as shown in FIG. 3D, so as to achieve a reduced degree of difficulty in fabrication process as well as a lower inductance value. In this method according to the embodiment, because of not having to fabricate a plurality of blind holes for connecting with the capacitor, and without having to consider issues such as contraposition and the manufacturing of many circuit paths and blind holes, thereby providing a more simpler fabrication process; at the same time, a group of electrodes 10a of the capacitor 10 are electrical connected with a group of junctions 26 on the PCB, without passing through the insulating layer, so that the circuit path 18 is shorter and the capacitance is lower.

Moreover, as shown in FIG. 3C, a group of electrodes 10a in the electronic elements 10 are aligned to a group of junctions 26 on the PCB, respectively; and the electronic elements 10 are assembled on the PCB through the group of junctions 26; then the metal layer 30 is laminated on the PCB, which already includes the electronic elements 10 that are embedded using the gel film such as dielectric gel, as shown in FIG. 3D.

In regards to the group of junctions 26 which are used for electrically connecting to the capacitor 10, the fabrication method for the group of junctions 26 can use either a conductive line or an insulated line comprising of conductive electroplating for manufacturing. However, to achieve the effect of a high density PCB, it is preferable to adopt an insulated line circuit for fabrication. As shown in FIG. 3A, the method according to the embodiment first provides a substrate 20 for the PCB, and a thin copper layer 22 formed on the substrate 20 (which can conduct the electroplating current). Then, as shown in FIG. 3B, a patterned photoresist layer 24 is formed on the thin copper layer 22 on the substrate 20. Because the patterned photoresist layer 24 at least is able to define the group of junctions 26, which are used for electrically connecting with the electronic elements 10, the electroplating current is flowed through the thin copper layer 22 to form the group of junctions 26 by means of electroplating method on the thin copper layer 22 based on the patterned photoresist layer 24. At last, after removing the patterned photoresist layer 24, the capacitor 10 is assembled as shown in FIG. 3C.

For further achieving a higher density PCB, after fabricating the structure as shown in FIG. 3D, the substrate 20, originally used for structural support, can be removed underneath the group of junctions 26, and the thin copper layer 22 for providing the electroplating current can also be removed for the sake of providing much more circuit space, as shown in FIG. 3E. After removing the substrate 20 and the thin copper layer 22, the group of junctions 26 which can be formed by electroplating method is exposed. Thereafter, the metal layer 30 is patterned into a trace layer 30a for completing the fabrication of the thin core.

In a word, this method not only can achieve lower inductance, but also to be able of having the trace manufactured as thin as possible. Meanwhile, the use of the lamination method is able to avoid the problem of contraposition of the blind holes and to more easily to manufacture many junctions. The embedded capacitor which is manufactured by this structure is able to achieve a lower inductance, and includes improved electrical performance properties for the PCB.

Although the present invention has been described with reference to the preferred embodiment thereof, it is apparent to those skilled in the art that a variety of modifications and changes may be made without departing from the scope of the present invention which is intended to be defined by the appended claims.

1. A method for embedding a plurality of electronic elements in a printed circuit board (PCB), comprising:
aligning a group of electrodes of the electronic elements to a group of junctions on the PCB, respectively;
assembling the electronic elements on the PCB through the group of junctions; and
laminating a metal layer on the PCB above the electronic elements and the group of junctions using a gel film, wherein the electronic elements are embedded in the gel film between the group of junctions and the metal layer.

2. The method for embedding the electronic elements as claimed in claim 1, further comprising:
providing a substrate for the PCB and a thin copper layer formed on the substrate;
forming a patterned photoresist layer on the thin copper layer on the substrate, the patterned photoresist layer at least defining the group of junctions for electrically connecting with the electronic elements;
electroplating to form the group of junctions on the thin copper layer based on the patterned photoresist layer by means of electroplating current flowing through the thin copper layer: and
removing the patterned photoresist layer.

3. The method for embedding the electronic elements as claimed in claim 2, further comprising:
removing the substrate and the thin copper layer, and exposing the group of junctions; and
patterning the metal layer into a circuit layer for completing the fabrication of a thin core.

4. The method for embedding the electronic elements as claimed in claim 1, wherein the electronic elements are in the form of a capacitor, a resistor, or a diode.

5. A structure of embedded electronic elements in a printed circuit board (PCB), comprising:
a group of junctions, disposed in the PCB;
a plurality of electronic elements, comprising a group of electrodes aligned to the group of junctions on the PCB, the electronic elements being assembled on the PCB through the group of junctions;
a gel film, laminated on the group of junctions and on the electronic elements for embedding the electronic elements and the group of junctions; and
a trace layer, formed on the gel film above the electronic elements and the group of junctions;
wherein the electronic elements are embedded in the gel film between the group of junctions and the trace layer.

6. The structure of embedded electronic elements as claimed in claim 5, wherein the electronic elements are in the form of a capacitor, a resistor, or a diode.
